(19) United States
(12) Patent Application Publication
(10) Pub. No.: US 2026/0068748 A1
(43) Pub. Date: Mar. 5, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Ryota KIYA, Himeji Hyogo (JP); Hideaki KITAZAWA, Himeji Hyogo (JP); Daiki WATANABE, Himeji Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/976,622

(22) Filed: Dec. 11, 2024

(30) Foreign Application Priority Data
Aug. 30, 2024 (JP) 2024-149959

(51) Int. Cl. H01L 23/10; H01L 23/00; H01L 23/367; H01L 23/495

(52) U.S. Cl. CPC H01L 23/10

(57) ABSTRACT

According to the present embodiment, a semiconductor device includes a semiconductor element and a frame. The semiconductor element has a first electrode surface and a second electrode surface opposed to the first electrode surface. The frame is arranged around the semiconductor element and has an opening facing the first electrode surface. The frame includes a first structure and a second structure. The first structure extends from an end of the semiconductor element to inside of the first electrode surface and has a first surface facing the first electrode surface. The second structure extends further to inside of the first electrode surface from the first structure and has a second surface that faces the first electrode surface and is different from the first surface.

### CROSS-REFERENCE TO RELATED APPLICATIONS

This application is based upon and claims the benefit of priority from the prior Japanese Patent Application No. 2024-149959, filed on Aug. 30, 2024 the entire contents of which are incorporated herein by reference.

### FIELD

Embodiments of the present invention relate to a semiconductor device.

### BACKGROUND

There is a semiconductor device in which a thermal compensation plate is brought into contact with an electrode surface of an internal semiconductor element with pressure in order to dissipate heat from the semiconductor element. For alignment in this case, a frame is arranged around the semiconductor element. An adhesive is provided between the frame and the semiconductor element.

However, overflowing of adhesive is difficult to control, and the overflowing adhesive may be brought into contact with the thermal compensation plate with pressure. In such a case, adhesion between the semiconductor element and the thermal compensation plate deteriorates, resulting in a non-uniform contact state.

### BRIEF DESCRIPTION OF THE DRAWINGS

FIG. 1 is a schematic cross-sectional view of a semiconductor device according to an embodiment of the present invention;

FIG. 2 is a top view illustrating a configuration example of a semiconductor element chip;

FIG. 3 is a cross-sectional view of a semiconductor element taken along a line A-A′;

FIG. 4 is a schematic top view of the semiconductor element chip as viewed from the side of a first electrode block;

FIG. 5 is a cross-sectional view of a cross-section taken along a line B-B′ in FIG. 4;

FIG. 6 is a cross-sectional view of a cross-section taken along a line C-C′ in FIG. 4;

FIG. 7 is a cross-sectional view of a frame in a comparative example; and

FIG. 8 is a diagram illustrating a side portion of a second structure.

### DETAILED DESCRIPTION

According to the present embodiment, a semiconductor device includes a semiconductor element and a frame. The semiconductor element has a first electrode surface and a second electrode surface opposed to the first electrode surface. The frame is arranged around the semiconductor element and has an opening facing the first electrode surface. The frame includes a first structure and a second structure. The first structure extends from an end of the semiconductor element to inside of the first electrode surface and has a first surface facing the first electrode surface. The second structure extends further to inside of the first electrode surface from the first structure and has a second surface that faces the first electrode surface and is different from the first surface.

Embodiments of the present invention will be explained below with reference to the drawings. In the following descriptions, identical or like members and the like are denoted by like reference signs and explanations of those already explained are omitted as appropriate.

### First Embodiment

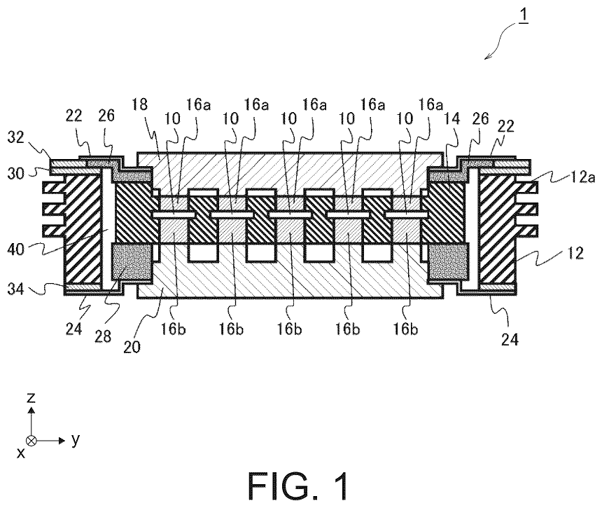

FIG. 1 is a schematic cross-sectional view of a semiconductor device according to a first embodiment of the present invention. A semiconductor device 1 of the present embodiment is a pressure-contact semiconductor device, for example. The semiconductor device 1 of the present embodiment is a PPI (press pack IEGT), for example.

The semiconductor device 1 of the present embodiment includes a plurality of semiconductor element chips 10, a housing 12, a resin frame 14, a first thermal compensation plate 16a, a second thermal compensation plate 16b, a first electrode block 18, a second electrode block 20, a first flange 22, a second flange 24, a first protection member 26, a second protection member 28, a first metal plate 30, a second metal plate 32, and a third metal plate 34.

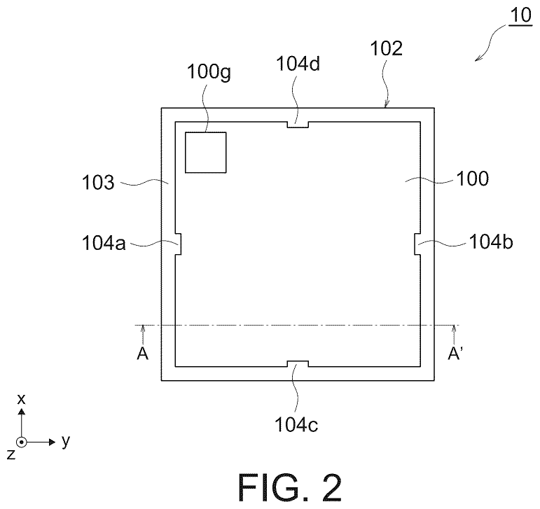

The semiconductor device 1 of the present embodiment includes the semiconductor element chips 10 arranged therein. Each semiconductor element chip 10 has a square planar shape with a side of 10 mm or more and 20 mm or less, for example. Details of the semiconductor element chip 10 will be described later by way of FIGS. 2 to 6.

The semiconductor element chips 10 are arranged inside the housing (first frame) 12. The housing 12 is annular and made of ceramic, for example. The housing 12 has a cylindrical shape, for example. The inner diameter of the housing 12 is 80 mm or more, for example. The thickness in the radial direction of the housing 12 is 4 mm or more and 20 mm or less, for example.

The resin frame 14 is provided inside the housing 12. At least a portion of the resin frame 14 is provided between the first electrode block 18 and the second electrode block 20. The resin frame 14 is made of resin. The resin frame 14 holds the semiconductor element chips 10. The resin frame 14 has a function of ensuring the insulation distance between the semiconductor element chips 10 and a function of aligning the semiconductor element chips 10.

The first thermal compensation plate 16a is provided on the first surface side of each semiconductor element chip 10. The second thermal compensation plate 16b is provided on the second surface side of each semiconductor element chip 10. To the first thermal compensation plate 16a and the second thermal compensation plate 16b, a material having a thermal expansion coefficient close to that of the semiconductor element chip 10 is applied. For example, in a case where a semiconductor element included in the semiconductor element chip 10 is a device using silicon, molybdenum of which the thermal expansion coefficient is close to that of silicon is applied as the material.

The first electrode block 18 is provided on the first surface side of each semiconductor element chip 10. The second electrode block 20 is provided on the second surface side of each semiconductor element chip 10. The first electrode block 18 and the second electrode block 20 are columnar, for example.

The first electrode block 18 is provided to be in contact with the thermal compensation plate 16a, and the second electrode block 20 is provided to be in contact with the thermal compensation plate 16b. The first electrode block 18 and the second electrode block 20 are made of metal, for example, copper.

The first flange 22 is provided around the first electrode block 18. The first flange 22 is annular. The first flange 22 is made of metal, for example, copper or stainless. The first electrode block 18 is an emitter pressure-contact electrode plate, and the second electrode block 20 is a collector pressure-contact electrode plate, for example.

The first flange 22 connects the first electrode block 18 and the housing 12 to each other. The first flange 22 is connected to the housing 12 via the first metal plate 30 and the second metal plate 32. The first metal plate 30 and the second metal plate 32 are made of metal being higher than the first flange 22 in melting point and property of adhesion to ceramic, for example.

The second flange 24 is provided around the second electrode block 20. The second flange 24 is annular. The second flange 24 is made of metal, for example, copper or stainless. The second flange 24 connects the second electrode block 20 and the housing 12 to each other. The second flange 24 is connected to the housing 12 via the third metal plate 34. The third metal plate 34 is made of metal being higher than the second flange 24 in melting point and property of adhesion to ceramic, for example. The third metal plate 34 is made of iron-nickel alloy, for example.

Here, a configuration example of the semiconductor element chip 10 is described. FIG. 2 is a top view illustrating a configuration example of the semiconductor element chip 10. As illustrated in FIG. 2, the semiconductor element chip 10 includes a semiconductor element 100 and a frame 102. FIG. 2 further illustrates a gate pad electrode 100g of the semiconductor element 100.

The semiconductor element 100 has a first electrode surface and a second electrode surface opposed to the first electrode surface. The semiconductor element 100 is an IEGT (Injection Enhanced Gate Transistor) using silicon (Si), for example. The IEGT is an IGBT (Insulated Gate Bipolar Transistor) having an electron injection promotion effect.

The surrounding portion of the semiconductor element 100 has been subjected to, for example, SIPOS (Semi-Insulated POlycrystalline Silicon) passivation in order to stably keep a high breakdown voltage of, for example, 4.5 kV. The frame 102 is adhered on the surrounding portion in order to obtain an insulation path and perform alignment in assembly.

The frame 102 is formed of a resin member, for example. The frame 102 is arranged around the semiconductor element 100 and has an opening that faces the first electrode surface of the semiconductor element 100. The frame 102 includes a first structure 103 and second structures 104a to 104d. The first structure 103 extends from an end of the semiconductor element 100 to inside of the first electrode surface and has a first surface facing the first electrode surface and having a first slope with respect to the first electrode surface. The second structures 104a to 104d extend further to inside of the first electrode surface from the first structure 103 and each have a second surface facing the first electrode surface. Although the second structures 104a to 104d each have a convex shape in the present embodiment, the shape is not limited thereto. For example, the second structures 104a to 104d may also be arranged to surround the outer periphery of the semiconductor element 100, similarly to the first structure 103.

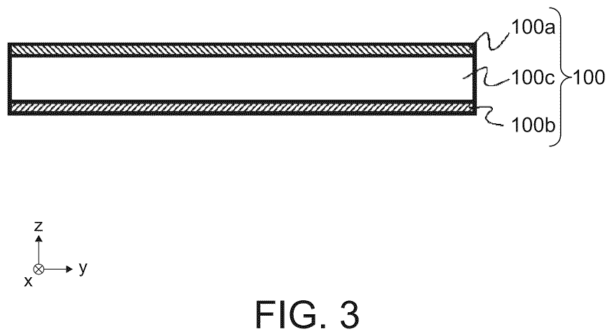

FIG. 3 is a cross-sectional view of the semiconductor element 100 taken along a line A-A′. As illustrated in FIG. 3, the semiconductor element 100 includes a first pad electrode 100a on the first electrode surface and a second pad electrode 100b on the second electrode surface opposite to the first electrode surface. A region between the first pad electrode 100a and the second pad electrode 100b serves as a semiconductor element region 100c. The first pad electrode 100a is an emitter electrode, for example. The second pad electrode 100b is a collector electrode, for example. The gate pad electrode 100g (see FIG. 2) is a gate electrode, for example. In addition, an aluminum (Al) layer may be arranged above (in the z-direction) the first pad electrode 100a and below the second pad electrode 100b.

The semiconductor element 100 is not particularly limited to any form as long as it is a device having electrodes on the top and bottom, and may be a diode such as an FRD (Fast Recovery Diode). Further, the semiconductor element 100 may be a MOSFET (Metal Oxide Semiconductor Field Effect Transistor). An IEGT and an FRD may both be mounted, for example. The semiconductor element 100 may be an RC-IEGT (Reverse Conducting-IEGT) in which a diode and an IEGT are packed into one chip. Furthermore, the semiconductor element 100 is not limited to a device using silicon and may be a device using silicon carbide (SiC).

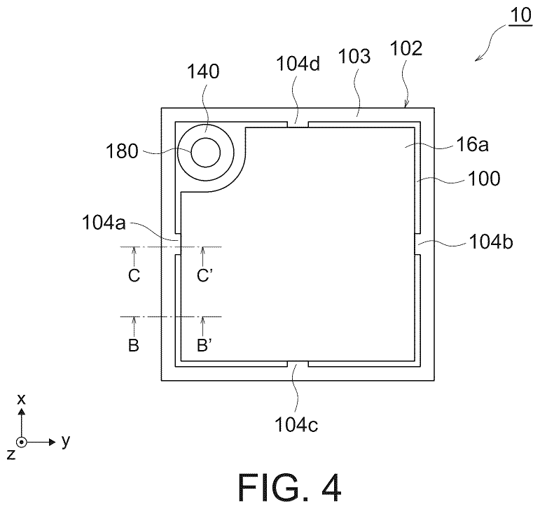

FIG. 4 is a schematic top view of the semiconductor element chip 10 as viewed from the first electrode block 18 side. With reference to FIG. 1, as illustrated in FIG. 4, the semiconductor element chip 10 is packed with pressure by the electrode blocks 18 and 20 from above and below via the thermal compensation plates 16a and 16b.

A gate pin 180 is in contact with the gate pad electrode 100g (see FIG. 2) of the semiconductor element 100 via a chip guide 140 of the resin frame 14. For example, the gate pin 180 is connected to a gate circuit for driving and controlling the semiconductor element 100, and the gate circuit is connected to the second pad electrode 100b (see FIG. 3).

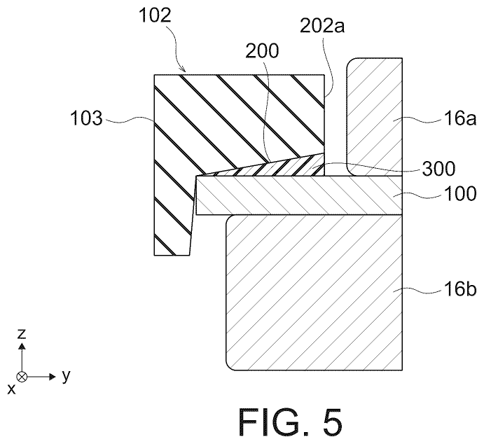

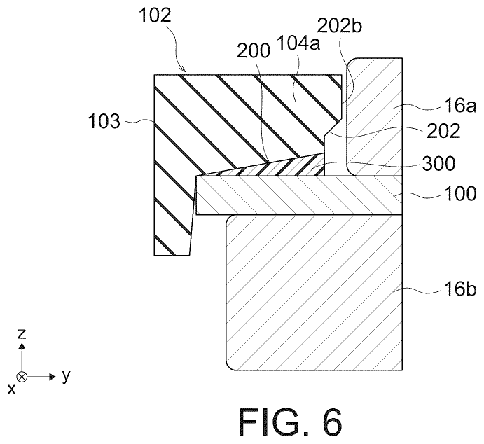

FIG. 5 is a cross-sectional view of a cross-section taken along a line B-B′ in FIG. 4. FIG. 6 is a cross-sectional view of a cross-section taken along a line C-C′ in FIG. 4. As illustrated in FIGS. 5 and 6, the frame 102 is a structure extending from an end of the semiconductor element 100 to inside of the first electrode surface. Although the following descriptions may be provided by taking the second structure 104a as an example, the second structures 104b to 104d also have the equivalent structure to that of the second structure 104a.

A surface of the frame 102, which faces the first electrode surface, includes a first surface 200 and a second surface 202 that have at least two different slopes with respect to the first electrode surface. That is, the first structure 103 is a structure having the first surface 200. The second structures 104a to 104d are structures each having the second surface 202. A surface with a slope may be referred to as “tapered surface” in some cases.

The first surface 200, which is located to be closer to the end of the semiconductor element 100 than the second surface 202 is arranged to surround the outer periphery of the semiconductor element 100. The first surface 200 has such a slope that the distance from the first electrode surface increases from the end of the semiconductor element 100 to inside of the first electrode surface.

An adhesive 300 is arranged between the first surface 200 and the first electrode surface of the semiconductor element 100. The adhesive 300 is made of a resin material having satisfactory adhesion to both the frame 102 and the semiconductor element 100, for example. The adhesive 300 is made of a resin material having satisfactory adhesion to metal, for example, silicone resin.

As illustrated in FIG. 6, a step is formed between one of the surfaces 200 and 202 having two different slopes, which is located on the inner side of the first electrode surface than the first surface 200, that is, the second surface 202 and the first surface 200. The second surface 202 has such a slope that the distance from the first electrode surface increases from the end of the semiconductor element 100 to inside of the first electrode surface.

The slope of the second surface 202 with respect to the first electrode surface is steeper than the slope of the first surface 200 with respect to the first electrode surface, for example. That is, if the distance from the end of the semiconductor element 100 to inside is the same, an increase in the distance between the second surface 202 and the first electrode surface is larger than an increase in the distance between the first surface 200 and the first electrode surface.

Referring back to FIG. 2, the frame 102 is configured in such a manner that the second structures 104a to 104d each having the slope of the second surface 202 are convex towards inside of the first electrode surface. An end surface 202b (see FIG. 6) of each of the second structures 104a to 104d, which is located inside the first electrode surface is formed on the inner side of the first electrode surface than an end surface 202a (see FIG. 5) of the first structure 103 not configuring the second structures 104a to 104d, which is located inside the first electrode surface.

More specifically, the first electrode surface of the semiconductor element 100 has at least two pairs of sides opposed to each other, and the frame 102 constitutes the second structure 104a, 104b, 104c, or 104d for each one of the opposed sides. Accordingly, the frame 102 limits the range of movement of the first thermal compensation plate 16a along the first electrode surface by the end surfaces 202b of the second structures 104a to 104d, which are located inside the first electrode surface. That is, ends of the second structures 104a to 104d, which are located on the inner side of the first electrode surface, limit the range of movement of the first thermal compensation plate 16a along the first electrode surface.

As described above, a region between the first surface 200 and the first electrode surface of the semiconductor element 100 serves as a region where the adhesive 300 is arranged. Meanwhile, the second structures 104a to 104d are used for placing the first thermal compensation plate 16a at a target position on the first electrode surface of the semiconductor element 100.

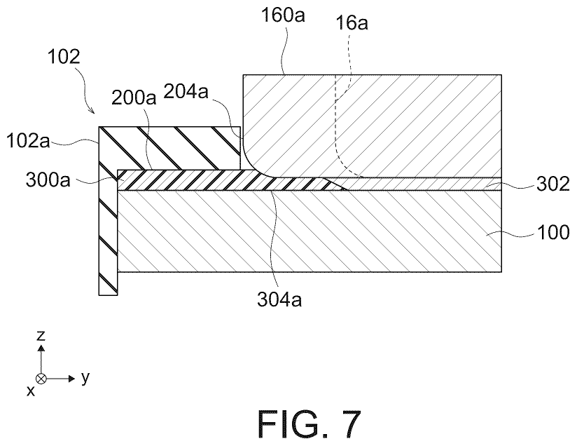

Here, technical effects of the first surface 200 and the second surface 202 are described with reference to FIG. 7. FIG. 7 is a cross-sectional view of a frame 102a in a comparative example.

The frame 102a in the comparative example has an opposed surface 200a parallel to the first electrode surface of the semiconductor element 100. An end surface 204a of the frame 102a, located inside the first electrode surface is used for alignment of a first thermal compensation plate 160a. An adhesive 300a is arranged between the opposed surface 200a and the first electrode surface of the semiconductor element 100. As described above, in the frame 102a in the comparative example, the opposed surface 200a is arranged around the semiconductor element 100 with the same width. Further, an aluminum member 302 is arranged on the first electrode surface of the semiconductor element 100.

The adhesive 300a may overflow from between the opposed surface 200a of the frame 102a and the first electrode surface. In this case, since the end surface 204a is used for alignment of the first thermal compensation plate 160a in the comparative example, a so-called stepped-on region 304a stepped on by the first thermal compensation plate 160a may be generated. Due to high pressure applied to the first thermal compensation plate 160a, the stepped-on region 304a spreads along the first electrode surface of the semiconductor element 100. Consequently, adhesion between the semiconductor element 100 and the thermal compensation plate 160a deteriorates, resulting in a non-uniform contact state. Accordingly, contact electric resistance between the semiconductor element 100 and the thermal compensation plate 160a increases, and unbalanced current can easily cause breakdown.

Meanwhile, in the frame 102 according to the present embodiment, alignment is performed by the end surfaces 202b (see FIG. 6) of the second structures 104a to 104d. For example, as illustrated in FIG. 7, the first thermal compensation plate 16a is arranged at a position away from the end surface 202a of the frame 102 (see FIG. 5), and therefore the possibility that a stepped-on region is generated is reduced even if the adhesive 300 overflows from the first surface 200.

In this case, the first surface 200 has such a slope that the distance from the first electrode surface increases from the end of the semiconductor element 100 to inside of the semiconductor element 100. Therefore, the thickness of the adhesive 300 also becomes thicker from the end of the semiconductor element 100 towards inside. Consequently, formation of the adhesive 300 is promoted toward the opening, and spreading to the back surface is prevented.

Further, by forming the second surface 202, the creepage distance to the surface 202b is ensured, and the adhesive is prevented from flowing to the surface 202b.

Referring back to FIG. 4, by arranging the second structures 104a to 104d in some regions of the frame 102, gaps are formed between the first thermal compensation plate 16a and the end surface 202a (see FIG. 5). Accordingly, an overflowing state of the adhesive 300 can easily be confirmed visually.

As described above, the frame 102 is configured to include the first structure 103 extending from an end of the semiconductor element 100 to inside of the first electrode surface and having the first surface 200 that faces the first electrode surface and has the first slope with respect to the first electrode surface, and the second structures 104a to 104d extending further to inside of the first electrode surface from the first structure 103 and having the second surface 202 facing the first electrode surface. Accordingly, in a case where the adhesive 300 is arranged between the first surface 200 and the first electrode surface, the end surfaces 202b of the second structures 104a to 104d can be arranged on the inner side of the first electrode surface than an end of the first surface 200. Consequently, the adhesive 300 and the first thermal compensation plate 16a are made apart from each other by the second structures 104a to 104d, and therefore the adhesive 300 can be prevented from being brought into contact with the first thermal compensation plate 16a with pressure even if the adhesive 300 overflows from between the first surface 200 and the first electrode surface.

### (First Modification of First Embodiment)

The semiconductor device 1 according to a first modification of the first embodiment is different from the semiconductor device 1 according to the first embodiment in that a slope is also formed laterally in each of the second structures 104a to 104d. Differences from the semiconductor device 1 according to the first embodiment are described below.

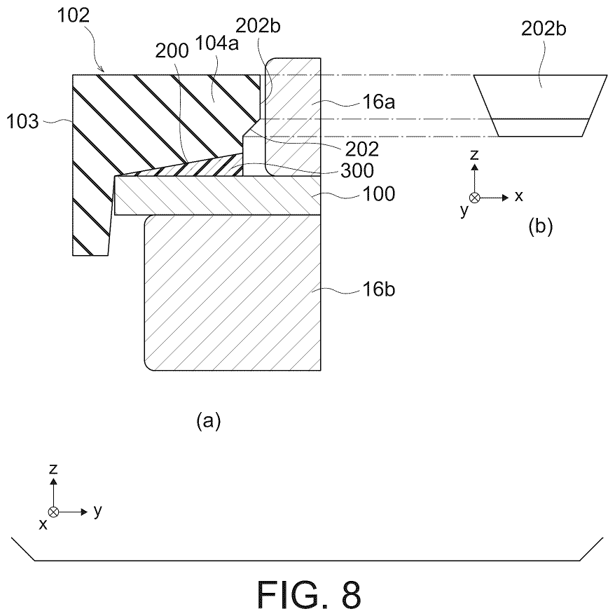

FIGS. 8A and 8B are diagrams illustrating a side portion of the second structure 104a. FIG. 8A is a diagram equivalent to FIG. 6. FIG. 8B is a front view of the second structure 104a as viewed through the first thermal compensation plate 16a.

As illustrated in FIG. 8B, the width of the second structure 104a in the direction along the first electrode surface of the semiconductor element 100 and in the direction (the x-direction) perpendicular to the direction from an end of the semiconductor element 100 to inside of the semiconductor element 100 increases as further separating from the first electrode surface. That is, the lateral width (in the x-direction) of the first surface 200 of the second structure 104a being convex is smaller than the lateral width (in the x-direction) of a termination portion of the second surface 202.

As described above, a slope is also formed in the lateral direction (the x-direction) in each of the second structures 104a to 104d being convex. With this configuration, visibility of the second structures 104a to 104d is more enhanced, so that alignment of the first thermal compensation plate 16a is more simplified.

While certain embodiments of the present invention have been described, these embodiments have been presented by way of example only, and are not intended to limit the scope of the inventions. Indeed, the embodiments described herein may be embodied in a variety of other forms; furthermore, various omissions, substitutions and changes in the embodiments may be made without departing from the spirit of the inventions. The embodiments and modifications thereof are intended to fall within the scope and spirit of the inventions and also the inventions and their equivalents described in the accompanying claims.

1. A semiconductor device comprising:
a semiconductor element having a first electrode surface and a second electrode surface opposed to the first electrode surface; and
a frame arranged around the semiconductor element and having an opening facing the first electrode surface, wherein
the frame includes
a first structure extending from an end of the semiconductor element to inside of the first electrode surface and having a first surface facing the first electrode surface, and
a second structure extending further to inside of the first electrode surface from the first structure and having a second surface that faces the first electrode surface and is different from the first surface.

2. The device of claim 1, wherein the first surface has such a slope that a distance between the first surface and the first electrode surface increases from the end of the semiconductor element to inside of the first electrode surface.

3. The device of claim 2, wherein the second surface has such a slope that a distance between the second surface and the first electrode surface increases from the end of the semiconductor element to inside of the first electrode surface.

4. The device of claim 3, wherein the slope of the second surface with respect to the first electrode surface is steeper than the slope of the first surface with respect to the first electrode surface.

5. The device of claim 1, wherein the first surface of the first structure is arranged to surround an outer periphery of the semiconductor element.

6. The device of claim 5, wherein the first surface and the second surface have a step therebetween.

7. The device of claim 6, further comprising an adhesive arranged between the first surface and the first electrode surface.

8. The device of claim 7, further comprising a first thermal compensation plate brought into contact with the first electrode surface with pressure, wherein
an end of the second structure, which is located inside the first electrode surface, limits a range of movement of the first thermal compensation plate along the first electrode surface.

9. The device of claim 8, wherein
the first electrode surface has at least two pairs of sides opposed to each other, and
the second structure is arranged to have a convex shape on each of the opposed sides.

10. The device of claim 9, wherein a width of the convex shape in a direction along the sides increases with an increase in a distance from the first electrode surface.

11. The device of claim 10, wherein the frame is formed of a resin member.

12. The device of claim 11, further comprising a second thermal compensation plate, wherein
the second electrode surface is in contact with the second thermal compensation plate.

13. The device of claim 12, further comprising:
a first electrode block; and
a second electrode block, wherein
the first thermal compensation plate and the second thermal compensation plate are brought into contact with pressure by the first electrode block and the second electrode block.

14. The device of claim 13, further comprising a resin frame, wherein
at least a portion of the resin frame is provided between the first electrode block and the second electrode block and holds the semiconductor element having the frame.

15. The device of claim 14, further comprising an annular housing, wherein
the resin frame is provided inside the annular housing.

16. The device of claim 15, wherein the first thermal compensation plate is made of molybdenum.

17. The device of claim 16, wherein the second thermal compensation plate is made of molybdenum.

18. The device of claim 1, wherein the semiconductor element is an IEGT.

19. The device of claim 1, wherein the semiconductor element is at least any of an IGBT, an FRD, and a MOSFET.

20. The device of claim 1, wherein the first electrode surface and the second electrode surface are each connected to at least any of an emitter electrode, a collector electrode, and a gate electrode of the semiconductor element.
